(19) United States
(12) Patent Application Publication
(10) Pub. No.: US 2024/0211649 A1
(43) Pub. Date: Jun. 27, 2024

(54) NUMERICAL SIMULATION METHOD OF INFLUENCE OF PTFE-BASED MEMBRANE ON AERODYNAMIC CHARACTERISTIC OF WIND TURBINE BLADE

(71) Applicants: CHINA THREE GORGES CORPORATION, Beijing (CN); CHINA THREE GORGES UNIVERSITY, Yichang City, Hubei (CN)

(72) Inventors: Jianping LIU, Beijing (CN); Xin XIANG, Beijing (CN); Jianhua WU, Nanjing, Jiangsu (CN); Zhiyu SUN, Beijing (CN); Yawei ZHU, Nanjing, Jiangsu (CN); Wenwei LI, Beijing (CN); Yajing LI, Beijing (CN); Hong WU, Nanjing, Jiangsu (CN); Jingxin ZHAO, Nanjing, Jiangsu (CN); Jianping WU, Nanjing, Jiangsu (CN); Hongwei MIN, Beijing (CN)

(21) Appl. No.: 17/640,726

(22) PCT Filed: Apr. 22, 2021
(86) PCT No.: PCT/CN2021/088985

§ 371 Date: Mar. 4, 2022

(30) Foreign Application Priority Data
Aug. 20, 2020 (CN) 202010845453.X

(51) Int. Cl. G06F 30/17

(52) U.S. Cl. CPC G06F 30/17

(57) ABSTRACT

The present invention disclosed a method for calibrating distributed hydrologic model parameters based on multipoint parallel correction, comprising: dividing the research-targeted basin into several sub-basins according to the position of the hydrometric stations of the main stream and larger tributaries within the research-targeted basin, when performing model parameter calibration, dividing the research-targeted basin into several parameter calibrated units according to the positional relationship of the sub-basins and the data situation of the hydrometric stations; integrating the hydrological model parameters of each parameter-calibrated unit to give the hydrological model parameters of the entire basin. The present invention has beneficial effects such as the research-targeted basin being divided into multiple parameter-calibrated units according to the distribution of the hydrometric stations having measured data, and different parameter-calibrated units on multiple computers being corrected and calibrated according to the measured flow process of the hydrometric stations at its outlet section, improving the calibration efficiency.

### CROSS-REFERENCE TO RELATED APPLICATIONS

This application is a national stage application of PCT/CN2021/088985. This application claims priorities from PCT Application No. PCT/CN2021/088985, filed Apr. 22, 2021, and from the Chinese patent application 202010845453.X filed Aug. 20, 2020, the content of which are incorporated herein in the entirety by reference.

### FIELD OF THE INVENTION

The present invention relates to the technical field of hydrologic forecast, in particular to a method for calibrating distributed hydrologic model parameters based on multipoint parallel correction.

### BACKGROUND OF THE INVENTION

At present, establishing a basin hydrologic model and calibrating hydrologic model parameters is indispensable as one of steps for studying questions such as reservoir regulation and water resource management.

The widely-used method for calibrating hydrologic model parameters is to establish an objective function for calibrating parameters with the flow process of basin outlet sections acting as a variable, and adopt various optimization algorithms or parallel algorithms to calibrate hydrologic model parameters. The method of directly adopting various optimization algorithms to establish an objective function for calibrating parameters with the flow process of basin outlet sections acting as a variable has a high requirement for computer memory, and it takes a long time to optimize the calculation. If a basin area is large, an ordinary computer will usually suspend the optimization program due to insufficient memory, without capability to give an optimal parameter, and the given model parameters are only calibrated according to the measured flow process at a single point of the entire basin outlet section, therefore, the given parameters may not be able to reflect the true runoff and convergence characteristics of each sub-basin in the basin.

### SUMMARY OF THE INVENTION

The objective of the present invention is to provide a method for calibrating distributed hydrologic model parameters based on multipoint parallel correction, so as to solve the aforementioned problems in the prior art.

In order to achieve the above object, the technical scheme adopted in the present invention is as follows:

A method for calibrating distributed hydrologic model parameters based on multipoint parallel correction, comprising the following steps:
S1. collecting the locations of precipitation stations and hydrometric stations within a research-targeted basin and their corresponding observed data to give a DEM map and a land use map of the research-targeted basin; performing analysis on the DEM map of the research-targeted basin to give a basin surface file of the research-targeted basin; dividing the research-targeted basin into several sub-basins and giving the precipitation stations within each sub-basin and the weight of each precipitation station, respectively; performing analysis on the land use map to give the impermeability rate of each sub-basin within the research-targeted basin;
S2. adding hydrologic units to the basin surface file to generate a basin model, and configuring corresponding calculation methods for each hydrologic unit;
S3. determining the rainfall process of each sub-basin and the flow process of each hydrometric station section within each sub-basin in the runoff process of flood rainfalls;
S4. dividing the research-targeted basin into several parameter-calibrated units, and creating calculation rules for the parameter-calibrated units;
S5. selecting the corresponding objective functions for each parameter-calibrated unit, and adopting an optimization algorithm to find the minimum value of the objective functions of each parameter-calibrated unit in parallel, gathering the minimum value of the objective functions given by each parameter-calibrated unit, thus being capable to give the optimal parameter of the hydrologic model of the research-targeted basin.

Preferably, S1 specifically includes the following sub steps:
S11. collecting the positional information of precipitation stations and hydrometric stations with observed data within the research-targeted basin and the observed data corresponding to the precipitation stations and the hydrometric stations, then converting the unequal time interval observed data into hourly observed data by means of an interpolation method; and giving the DEM map and the land use map of the research-targeted basin;
S12. performing hydrologic analysis on the DEM map of the research-targeted basin by means of GIS software to give the basin surface file within the research-targeted basin;
S13. dividing the research-targeted basin into several sub-basins by means of a basin division method; the basin division method ensuring that all the hydrometric stations and the reservoirs of the main stream and larger tributaries having measured data within the research-targeted basin are distributed at the outlet position of each sub-basin;
S14. drawing Thiessen polygons based on the precipitation stations within the research-targeted basin so as to give the influenced precipitation stations of each sub-basin within the research-targeted basin and their respective weights;
S15. analyzing the land use map within the research-targeted basin by means of GIS software to give the impermeability rate of each sub-basin within the research-targeted basin.

Preferably, when dividing the research-targeted basin into sub-basins, the hydrometric stations and/or reservoirs act as the outlet section of the sub-basin.

Preferably, S2 specifically includes adding the hydrologic units to the basin surface file to generate the basin model, and configuring the corresponding calculation methods for each hydrologic unit, the hydrologic units including a reservoir unit, a river unit, a sub-basin unit and a confluence unit.

Preferably, S3 specifically includes the following sub steps:
S31. determining the starting and ending time of rainfall runoff simulation according to the runoff process of the research-targeted basin outlet section and the rainfall process of each precipitation station;
S32. using surface precipitation within each sub-basin to represent the runoff process within each sub-basin, determining the surface precipitation on the basis of multiplication for the precipitation data of each precipitation station within the sub-basin and the Thiessen polygon weights of each precipitation station;
S33. the flow process of each hydrometric station adopting an hourly flow process.

Preferably, S4 specifically includes the following sub steps:
S41. according to the location of the hydrometric stations with observed data, dividing the research-targeted basin into several parameter-calibrated units, each of which contains at least one sub-basin, and ensuring that the outlet section of each parameter-calibrated unit is a hydrometric station with observed data;
S42. replacing the outflow process of the sub-basin whose outlet section is a reservoir unit with the actual outflow of the reservoir;
S43. for the parameter-calibrated unit that has other parameter-calibrated units flowing in, the outlet section flow of the other parameter-calibrated unit making use of the observed flow as its corresponding outflow data, that is, the inflow data of the parameter-calibrated unit flowed into.

Preferably, S5 specifically includes the following sub steps:
S51. each parameter-calibrated unit selecting an appropriate hydrologic model parameter to calibrate the objective function according to its respective requirement for basin hydrologic forecast, the objective function being a peak error percentage function or a mean-weighted root-mean-square error function, when required to impose limitations on planning and designing to peak flow, selecting the peak error percentage function as the objective function; when required to reflect the overall situation of the flood process and emphasize the simulation of flood peak flow, selecting the mean-weighted root-mean-square error function as the objective function; the peak error percentage function and the mean-weighted root-mean-square error function being respectively shown in Formula:

$${f}_{1} = 100 \times \vert \frac{{q}_{s} ( peak ) - {q}_{o} ( peak )}{{q}_{o} ( peak )} \vert$$

$${f}_{2} = {\{ \frac{1}{N Q} \times [ {\sum }_{i = 1}^{N Q} {( {q}_{o} ( i ) - {q}_{s} ( i ) )}^{2} ( \frac{{q}_{o} ( i ) + {q}_{o} ( mean )}{2 \times {q}_{o} ( mean )} ) ] \}}^{1 / 2}$$

where f₁ is the peak error percentage function; qₛ (peak) is the peak value to be calculated; qₒ (peak) is the measured peak value; f₂ is the mean-weighted root-mean-square error function; NQ is the number of the hydrograph ordinates to be calculated; qₒ(i) is the measured i^{th} period end flow; qₛ(i) is the i^{th} period end flow to be calculated; i is the time sequence;
S52. for each parameter-calibrated unit, finding the minimum value of its own objective function in parallel by means of one computers with the optimization algorithm, respectively, so as to achieve calibrating the hydrological model parameters within the research-targeted basin; the minimum value of each objective function being the optimal parameter calibrated by each parameter-calibrated unit; gathering the optimal parameters calibrated by each parameter-calibrated unit to give the optimal parameter of the hydrologic model of the research-targeted basin.

The present invention has beneficial effects as follows: 1. The research-targeted basin is divided into multiple parameter-calibrated units according to the distribution of the hydrometric stations having measured data, and different parameter-calibrated units are corrected and calibrated on multiple computers according to the measured flow process of the hydrometric station at its outlet section, improving the calibration efficiency. 2. In the case that the computer performance is not very high, it is still possible to obtain the hydrologic model parameters that can more truly reflect the true runoff and convergence characteristics through simple operations. 3. Parallel algorithms based on the parallel language MPI are used to encode the program for sensitivity analysis and multi-target calibration, and the sensitive parameters given by the open source program of a coupled hydrologic model based on an overall sensitivity analysis method are used for the multi-target calibration of model parameters to give an optimal solution, so the application of the parallel algorithm greatly improves the parameter calibration efficiency and saves a lot of time to optimize parameters.

### BRIEF DESCRIPTION OF THE DRAWINGS

FIG. 1 is a flow diagram of the method in the embodiment according to the present invention.

FIG. 2 is a distribution map of the precipitation stations upstream of Linyi in the embodiment according to the present invention.

FIG. 3 is a distribution map of the hydrometric stations upstream of Linyi in the embodiment according to the present invention.

FIG. 4 is a distribution map of the reservoirs upstream of Linyi in the embodiment according to the present invention.

FIG. 5 is a division map of the sub-basins upstream of Linyi in the embodiment according to the present invention.

FIG. 6 is a division map of the Thiessen polygons upstream of Linyi in the embodiment according to the present invention.

FIG. 7 is a schematic diagram of the hydrologic models upstream of Linyi in the embodiment according to the present invention.

FIG. 8 is a comparison chart between the measured flow and the flow to be calculated within the parameter-calibrated units upstream of Gegou in the embodiment according to the present invention.

FIG. 9 is a comparison chart between the measured flow and the flow to be calculated within the parameter-calibrated units upstream of Gaoli in the embodiment according to the present invention.

FIG. 10 is a comparison chart between the measured flow and the flow to be calculated within the parameter-calibrated units upstream of Jiaoyi in the embodiment according to the present invention.

FIG. 11 is a comparison chart between the measured flow and the flow to be calculated except the other three parameter-calibrated units upstream of Linyi in the embodiment according to the present invention.

FIG. 12 is an overall calibration effect chart of the basins upstream of Linyi in the embodiment according to the present invention.

### DETAILED DESCRIPTION OF SOME EMBODIMENTS

In order to make the objectives, technical solutions, and advantages of the present invention clearer, the present invention will be further described in detail in combination with the drawings as follows. It should be understood that the specific embodiment described herein are only used to explain the present invention, but not used to impose limitations on the present invention.

### Example 1

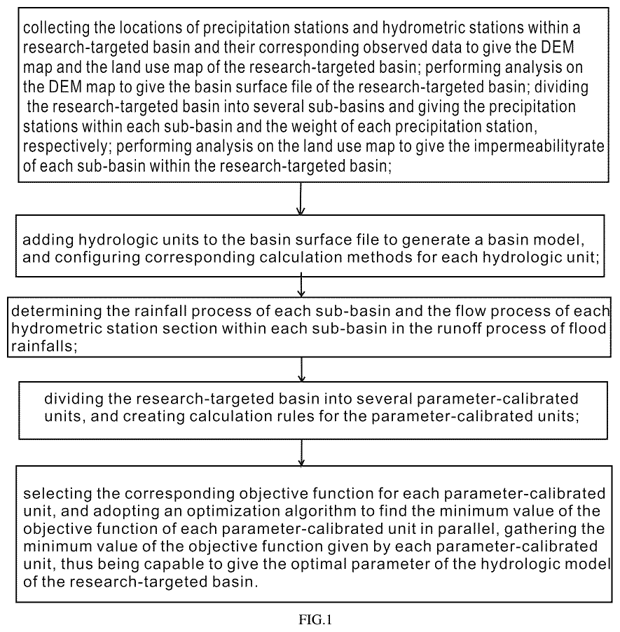

As shown in FIG. 1, in this example, a method for calibrating distributed hydrologic model parameters based on multipoint parallel correction is provided, comprising the following steps:
S1. collecting the locations of precipitation stations and hydrometric stations within a research-targeted basin and their corresponding observed data to give a DEM map and a land use map of the research-targeted basin; performing analysis on the DEM map of the research-targeted basin to give a basin surface file of the research-targeted basin; dividing the research-targeted basin into several sub-basins and giving the precipitation stations within each sub-basin and the weight of each precipitation station, respectively; performing analysis on the land use map to give the impermeability rate of each sub-basin within the research-targeted basin;
S2. adding hydrologic units to the basin surface file to generate a basin model, and configuring corresponding calculation methods for each hydrologic unit;
S3. determining the rainfall process of each sub-basin and the flow process of each hydrometric station section within each sub-basin in the runoff process of flood rainfalls;
S4. dividing the research-targeted basin into several parameter-calibrated units, and creating calculation rules for the parameter-calibrated units;
S5. selecting the corresponding objective functions for each parameter-calibrated unit, and adopting an optimization algorithm to find the minimum value of the objective functions of each parameter-calibrated unit in parallel, gathering the minimum value of the objective functions given by each parameter-calibrated unit, thus being capable to give the optimal parameter of the hydrologic model of the research-targeted basin.

In this example, the method specifically includes five parts, that is, the part of collecting and processing data, the part of creating a basin model, the part of determining the rainfall process of each sub-basin and the flow process of each hydrometric station section within the basin in the runoff process of flood rainfalls, the part of dividing the research-targeted basin into parallel parameter-calibrated units and creating calculation rules, and the part of choosing and optimizing an objective function and finding the minimum value of the objective function.

### Part 1: Collecting and Processing Data.

In this example, step S1 corresponds to part 1, specifically includes the following sub steps:
S11. collecting the positional information of precipitation stations and hydrometric stations with observed data within the research-targeted basin and the observed data corresponding to the precipitation stations and the hydrometric stations, then converting the unequal time interval observed data into hourly observed data by means of an interpolation method; and giving the DEM map and the land use map of the research-targeted basin;
S12. performing hydrologic analysis on the DEM map of the research-targeted basin by means of GIS software to give the basin surface file within the research-targeted basin;
S13. dividing the research-targeted basin into several sub-basins by means of a basin division method; the basin division method ensuring that all the hydrometric stations and the reservoirs of the main stream and larger tributaries having measured data within the research-targeted basin are distributed at the outlet position of each sub-basin;
S14. drawing Thiessen polygons based on the precipitation stations within the research-targeted basin so as to give the influenced precipitation stations of each sub-basin within the research-targeted basin and their respective weights;
S15. analyzing the land use map within the research-targeted basin by means of GIS software to give the impermeability rate of each sub-basin within the research-targeted basin.

In this example, when dividing the research-targeted basin into sub-basins, the hydrometric stations and/or reservoirs act as the outlet section of the sub-basin.

In this example, as the impermeability rate is a fixed parameter with meaning of physics for the hydrologic model; therefore, in step S15, the impermeability rate of each sub-basin needs to be calculated, so as to subsequently find the optimal parameter of the hydrologic model.

### Part 2: Creating a Basin Model.

In this example, step S2 corresponds to part 2, specifically including adding hydrologic units to the basin surface file to generate a basin model, and configuring corresponding calculation methods for each hydrologic unit, wherein the hydrologic units include a reservoir unit, a river unit, a sub-basin unit and a confluence unit.

In this example, hydrologic units has different calculation methods from each other. For example, the sub-basin unit needs to be provided with a method for calculating runoff generation, a method for calculating confluence and a method for calculating base flow; the river unit needs to be provided with a method for routing river flood; the reservoir unit needs to be provided with a method for calculating reservoir outflow. In this way, the hydrologic units adopt different calculation methods to perform corresponding calculations, respectively, so as to prepare for calculation in step S3.

Part 3: Determining the Rainfall Process of Each Sub-Basin and the Flow Process of Each Hydrometric Station Section within the Basin in the Runoff Process of Flood Rainfalls.

In this example, step S3 corresponds to part 3, specifically includes the following sub steps:
S31. determining the starting and ending time of rainfall runoff simulation according to the runoff process of the research-targeted basin outlet section and the rainfall process of each precipitation station;
S32. using surface precipitation within each sub-basin to represent the runoff process within each sub-basin, determining the surface precipitation on the basis of multiplication for the precipitation data of each precipitation station within the sub-basin and the Thiessen polygon weights of each precipitation station;
S33. the flow process of each hydrometric station adopting an hourly flow process.

In other words, step S3 specifically includes three steps, that is, firstly, determining the starting and ending time of rainfall runoff simulation according to the runoff process of the research-targeted basin outlet section and the rainfall process of each precipitation station, secondly, using the surface precipitation within sub-basins to represent the rainfall process of each sub-basin, wherein the surface precipitation is determined on the basis of multiplication for the previously-obtained hourly precipitation data of each precipitation station and the Thiessen polygon weights of each precipitation station, thirdly, the flow process of each hydrometric station adopting an hourly flow process.

Part 4: Dividing the Research-Targeted Basin into Parallel Parameter-Calibrated Units and Creating Calculation Rules.

In this example, step S4 corresponds to part 4, specifically includes the following sub steps:
S41. according to the location of the hydrometric stations with observed data, dividing the research-targeted basin into several parameter-calibrated units, each of which contains at least one sub-basin, and ensuring that the outlet section of each parameter-calibrated unit is a hydrometric station with observed data;
S42. replacing the outflow process of the sub-basin whose outlet section is a reservoir unit with the actual outflow of the reservoir;
S43. for the parameter-calibrated unit that has other parameter-calibrated units flowing in, the outlet section flow of the other parameter-calibrated unit making use of the observed flow as its corresponding outflow data, that is, the inflow data of the parameter-calibrated unit flowed into.

In this example, the part of dividing the research-targeted basin into parameter-calibrated units specifically includes the step of according to the location of the hydrometric station, dividing the research-targeted basin into several parameter-calibrated units, which respectively contain one or more sub-basins, and the outlet locations of which must be a hydrometric station with observed data.

In this example, the part of creating calculation rules of parameter-calibrated units specifically includes the step of processing the outflow process of the sub-basin whose outlet section is a reservoir unit by adopting the actual outflow of the reservoir. For the parameter-calibrated unit that has other parameter-calibrated units flowing in, the outlet section flow of the other parameter-calibrated unit makes use of the observed flow as its corresponding outflow data, that is, the inflow data of the parameter-calibrated unit flowed into.

### Part 5: Choosing and Optimizing an Objective Function and Finding the Minimum Value of the Objective Function.

In this example, step S5 corresponds to part 5, specifically includes the following sub steps:
S51. each parameter-calibrated unit selecting an appropriate hydrologic model parameter to calibrate the objective function according to its respective requirement for basin hydrologic forecast, the objective function being a peak error percentage function or a mean-weighted root-mean-square error function, when required to impose limitations on planning and designing to peak flow, selecting the peak error percentage function as the objective function; when required to reflect the overall situation of the flood process and emphasize the simulation of flood peak flow, selecting the mean-weighted root-mean-square error function as the objective function; the peak error percentage function and the mean-weighted root-mean-square error function being respectively shown in Formula:

$${f}_{1} = 100 \times \vert \frac{{q}_{s} ( peak ) - {q}_{o} ( peak )}{{q}_{o} ( peak )} \vert$$

$${f}_{2} = {\{ \frac{1}{N Q} \times [ {\sum }_{i = 1}^{N Q} {( {q}_{o} ( i ) - {q}_{s} ( i ) )}^{2} ( \frac{{q}_{o} ( i ) + {q}_{o} ( mean )}{2 \times {q}_{o} ( mean )} ) ] \}}^{1 / 2}$$

where f₁ is the peak error percentage function; qₛ(peak) is the peak value to be calculated; qₒ(peak) is the measured peak value; f₂ is the mean-weighted root-mean-square error function; NQ is the number of the hydrograph ordinates to be calculated; qₒ(i) is the measured i^{th} period end flow; qₛ(i) is the i^{th} period end flow to be calculated; i is the time sequence;
S52. for each parameter-calibrated unit, finding the minimum value of its own objective function in parallel by means of one computers with the optimization algorithm, respectively, so as to achieve calibrating the hydrological model parameters within the research-targeted basin; the minimum value of each objective function being the optimal parameter calibrated by each parameter-calibrated unit; gathering the optimal parameters calibrated by each parameter-calibrated unit to give the optimal parameter of the hydrologic model of the research-targeted basin.

In this example, for each parameter-calibrated unit, the calculation rules determined in step S4 are adopted, including steps of finding the minimum value of each objective function in parallel by means of several computers applying the optimization algorithm, so as to perform parallel parameter calibration on the hydrologic model, then gathering the optimal parameters calibrated by each parameter-calibrated unit to give the optimal parameter set of the hydrologic model of the research-targeted basin.

In this example, this method based on the parallel language MPI is used to encode the program for sensitivity analysis and multi-target calibration, and the sensitive parameters given by the open source program of a coupled hydrologic model based on an overall sensitivity analysis method are used for the multi-target calibration of model parameters to give an optimal solution; the parallel algorithm on multiple computers improves the parameter calibration efficiency.

### Example 2

In this example, calibrating hydrologic model parameters upstream of Linyi Hydrometric Station of Shandong Yihe is taken as an example to specifically describe the implementation process and the achieved effect of the method for calibrating parameters in the present invention.

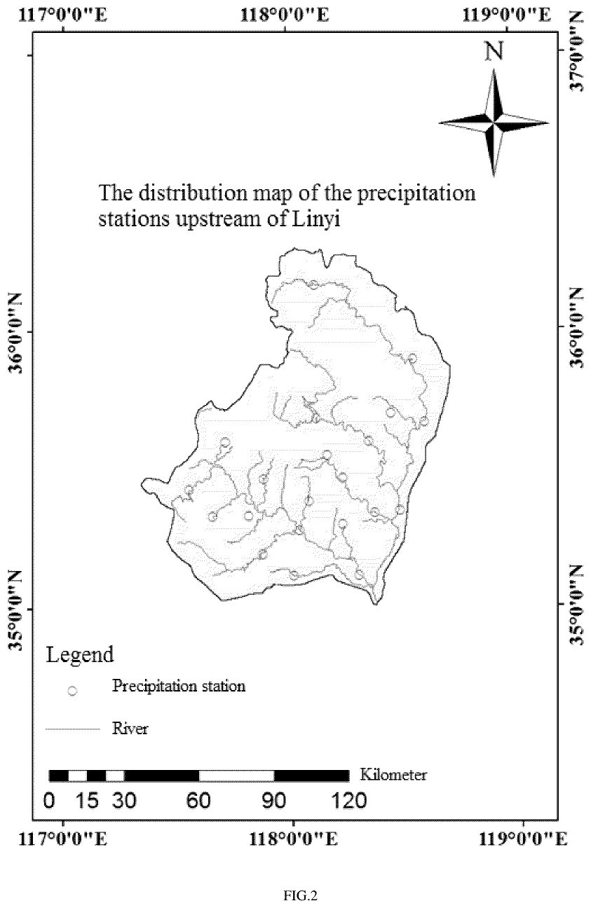

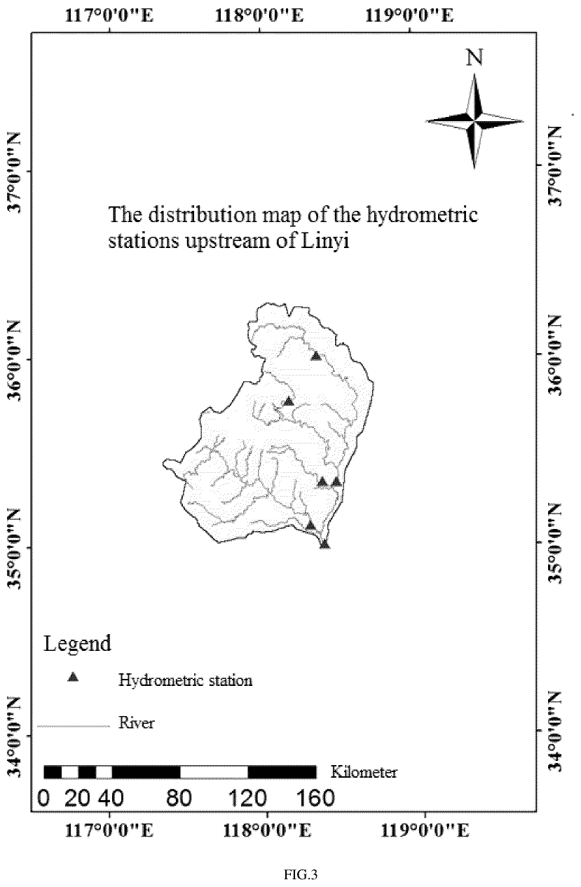

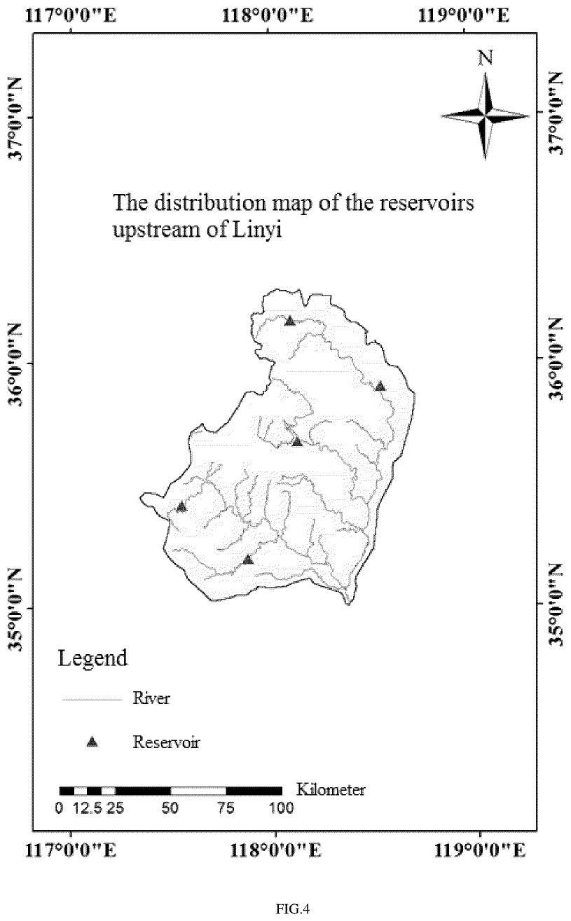

The Linyi Station has a catchment area of 10315 km², a river length of 227.8 km, and a terrain bulging in the northwest and sloping to the southeast plain. Due to the complex terrain upstream of the Yi River, many tributaries have been formed. The first-level tributaries upstream of the Linyi Station with a catchment area greater than 200 km² include the Dongwen River, the Meng River, the Beng River, the Su River and the Liuqing River. In the basin, mountain areas account for about 68%, and plain areas accounts for about 32%. The Yihe River basin belongs to a temperate zone continental climate, with average annual precipitation of 813 mm for many years, and rainfall of 600 mm during the flood season accounting for about 73.9% of the annual precipitation. There are 21 precipitation stations, 6 hydrometric stations on the main stream and larger tributaries, and 5 large reservoirs upstream of Linyi. The distribution map of the precipitation stations upstream of Linyi is shown as FIG. 2, the distribution map of the hydrometric stations therein is shown as FIG. 3, the distribution map of the reservoirs therein is shown as FIG. 4. Based on the rainfall data of 21 precipitation stations and the flow data of 4 hydrometric stations (Linyi, Gagou, Jiaoyi, Gaoli) upstream of Linyi with the starting and ending time from 1 a.m. on Jul. 14, 2017 to 3. p.m. on Jul. 20, 2017, parameter calibration is performed on the hydrologic model upstream of Linyi in this example. The method for calibrating distributed hydrologic model parameters based on multipoint parallel correction has the following steps:

### S1. Collecting and Processing Data.

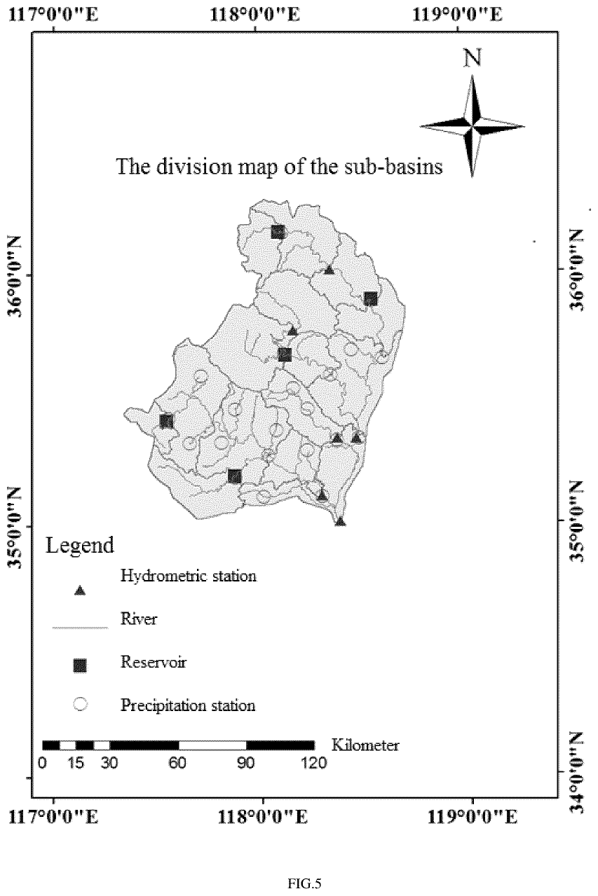

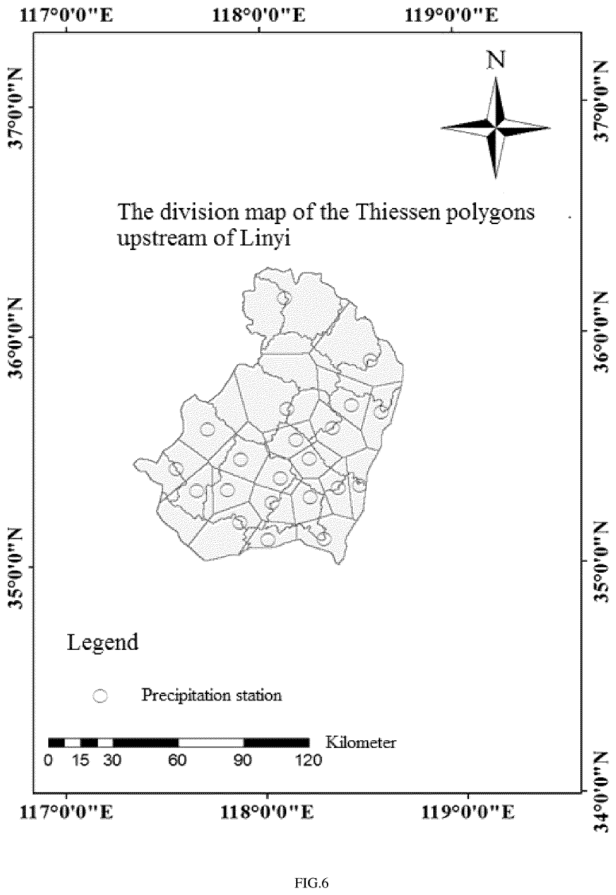

Taking the basin upstream of Linyi as a research-targeted basin, collecting the rainfall data of 21 precipitation stations and the flow data of 4 hydrometric stations (Linyi, Gagou, Jiaoyi, Gaoli) upstream of Linyi with the starting and ending time from 1 a.m. on Jul. 14, 2017 to 3. p.m. on Jul. 20, 2017, and interpolating these data from unequal time interval data into hourly data; collecting the DEM map and the land use map of the research-targeted basin, then performing hydrologic analysis on the DEM map by means of GIS software to give the basin surface file of the research-targeted basin, dividing the research-targeted basin into several sub-basins by means of a basin division method so as to ensure that all the hydrometric stations and the reservoirs of the main stream and larger tributaries having measured data within the research-targeted basin are distributed at the outlet position of each sub-basin(the division map of the sub-basins is shown in FIG. 5); analyzing the land use map by means of GIS software to give the impermeability rate of each sub-basin within the research-targeted basin; drawing the Thiessen polygons based on the precipitation stations within the research-targeted basin so as to give the influenced precipitation stations of each sub-basin within the research-targeted basin and their respective weights (the Thiessen polygons within the research-targeted basin are shown in FIG. 6).

### S2. Creating a Basin Model.

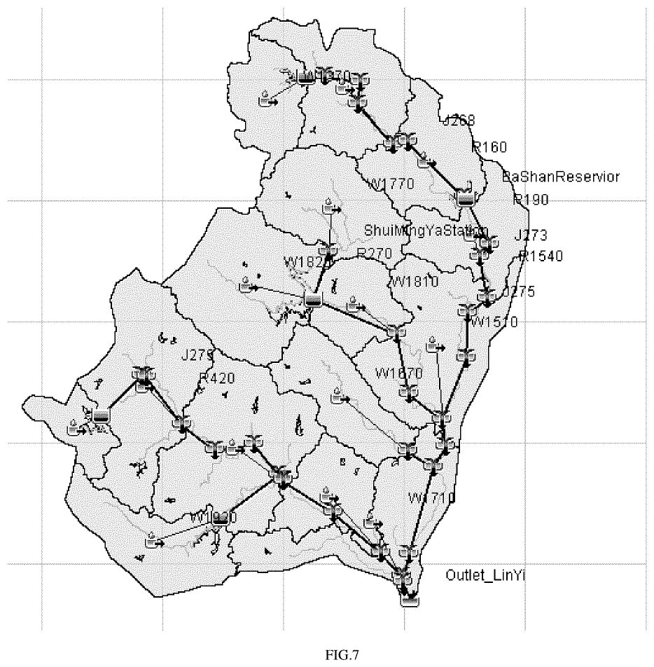

adding hydrologic units to the basin surface file to generate a basin model, and configuring corresponding calculation methods for each hydrologic unit, wherein the hydrologic units include a reservoir unit, a river unit, a sub-basin unit and a confluence unit (the established model upstream of Linyi is shown in FIG. 7).

S3. Determining the Rainfall Process of Each Sub-Basin and the Flow Process of Each Hydrometric Station Section within the Basin in the Runoff Process of Flood Rainfalls.

1. Determining the starting and ending time of rainfall runoff simulation as from 1 a.m. on Jul. 14, 2017 to 3. p.m. on Jul. 20, 2017 according to the runoff process of the research-targeted basin outlet section and the rainfall process of each precipitation station.

2. Using the surface precipitation within sub-basins to represent the rainfall process of each sub-basin, wherein the surface precipitation is determined on the basis of multiplication for the hourly precipitation data of each precipitation station obtained in S1 and the Thiessen polygon weights of each precipitation station.

3. The flow process of each hydrometric station adopting an hourly flow process.

S4. Dividing the Research-Targeted Basin into Parallel Parameter-Calibrated Units and Creating Calculation Rules.

1. Dividing the research-targeted basin into parameter-calibrated units:

According to the location of the hydrometric station with observed data, the research-targeted basin is divided into 4 parameter-calibrated units, which respectively are the basin upstream of Gegou, the basin upstream of Gaoli, the basin upstream of Jiaoyi, and basin part within the basin upstream of Linyi except the above 3 parameter-calibrated units, namely the W1710 sub-basin.

2. Creating calculation rules of parameter-calibrated units.

A. The outflow process of the 5 sub-basins whose outlet section are a reservoir unit (they are Tianzhuang Reservoir, Bashan Reservoir, Andi Reservoir, Tangcun Reservoir and Xujiaya Reservoir, respectively) is processed by adopting the actual outflow of the reservoir.

B. When calibrating the parameters of the W1710 sub-basin, the incoming water from Gegou, Gaoli, and Jiaoyi is processed according to the observed outflows from these three hydrometric stations.

### S5. Choosing and Optimizing an Objective Function and Finding the Minimum Value of the Objective Function.

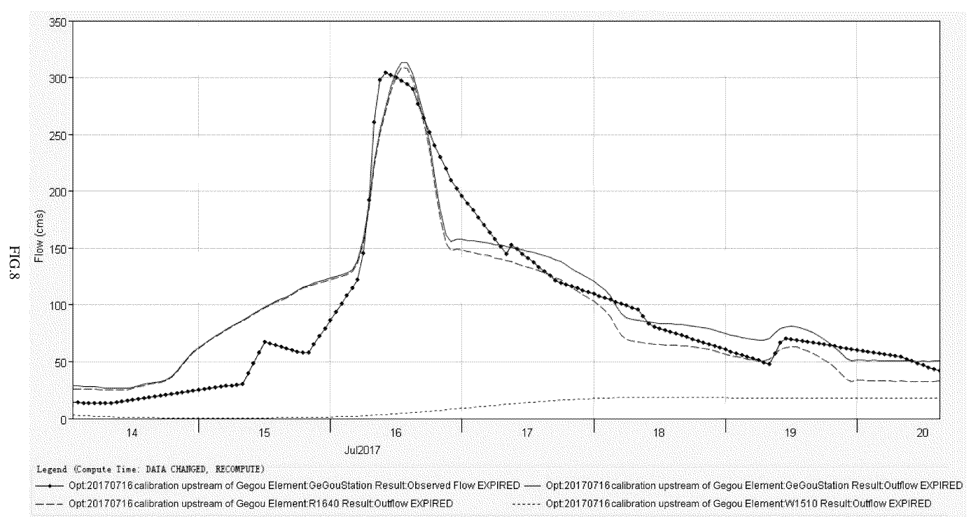

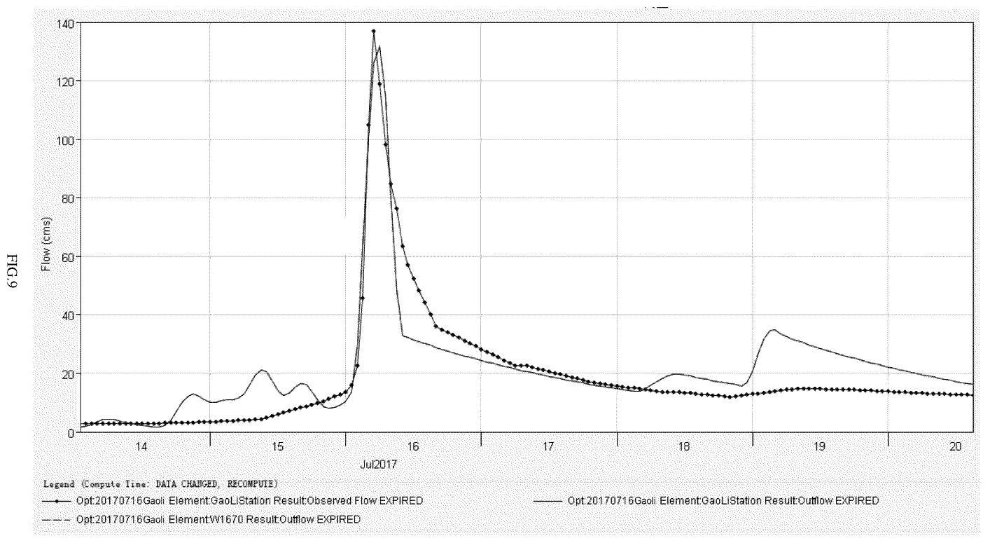

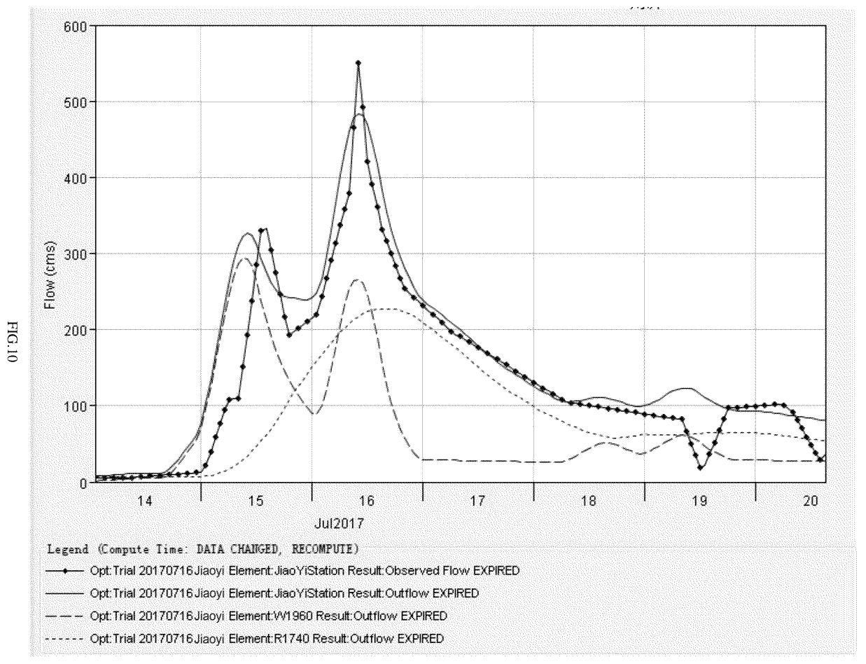

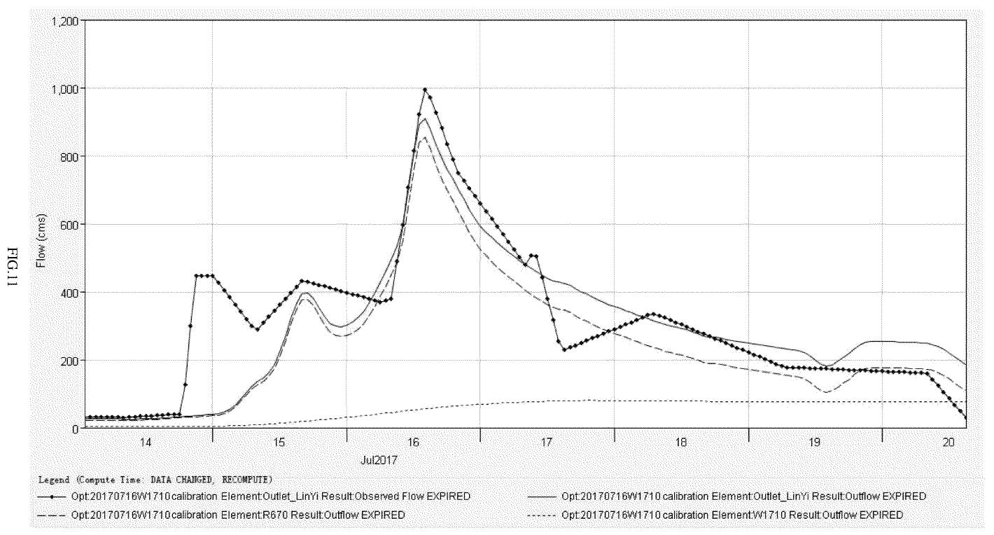

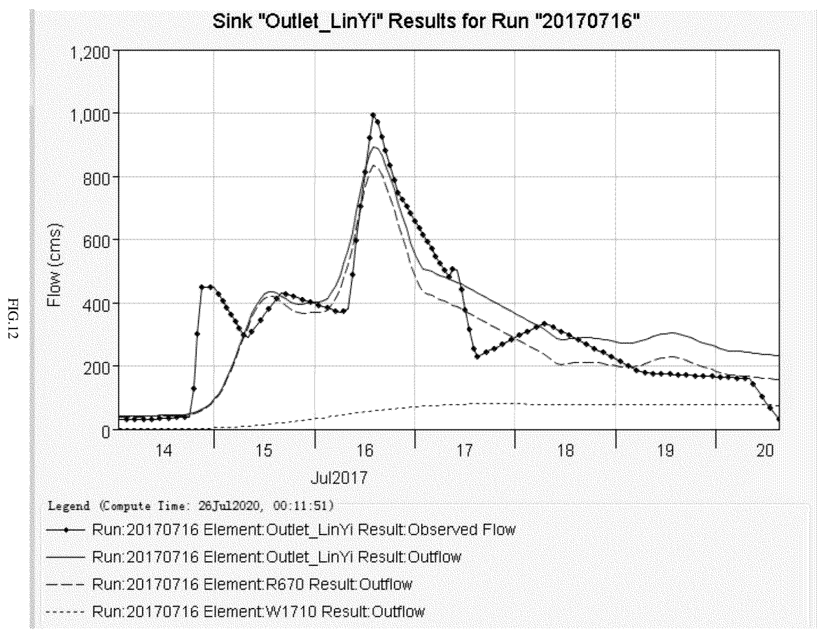

In this example, a mean-weighted root-mean-square error function is selected to calibrate the four parameter-calibrated units. To the four parameter-calibrated units, the optimization algorithm is applied on 4 computers to find the minimum value of the objective function in parallel, respectively, and perform parallel calibration on the hydrologic model. The comparison chart between the measured flow and the flow to be calculated within the parameter-calibrated units upstream of Gegou is shown in FIG. 8. The comparison chart between the measured flow and the flow to be calculated within the parameter-calibrated units upstream of Gaoli is shown in FIG. 9. The comparison chart between the measured flow and the flow to be calculated within the parameter-calibrated units upstream of Jiaoyi is shown in FIG. 10. The comparison chart between the measured flow and the flow to be calculated except the other three parameter-calibrated units upstream of Linyi is shown in FIG. 11. The overall calibration effect chart within the research-targeted basin is shown in FIG. 12. The optimal parameters calibrated by each parameter-calibrated unit are gathered to give the optimal parameter of the hydrologic model of the research-targeted basin.

By adopting the above-mentioned technical solutions disclosed by the present invention, we can achieve the following beneficial effects:

The present invention provides a method for calibrating distributed hydrologic model parameters based on multipoint parallel correction. In the present invention, the research-targeted basin is divided into multiple parameter-calibrated units according to the distribution of the hydrometric stations having measured data, and different parameter-calibrated units are corrected and calibrated on multiple computers according to the measured flow process of the hydrometric station at its outlet section, improving the calibration efficiency. In the case that the computer performance is not very high, it is still possible to obtain the hydrologic model parameters that can more truly reflect the true runoff and convergence characteristics through simple operations. Parallel algorithms based on the parallel language MPI are used to encode the program for sensitivity analysis and multi-target calibration, and the sensitive parameters given by the open source program of a coupled hydrologic model based on an overall sensitivity analysis method are used for the multi-target calibration of model parameters to give an optimal solution, so the application of the parallel algorithm greatly improves the parameter calibration efficiency and saves a lot of time to optimize parameters.

The aforementioned descriptions are only the preferred examples of the present invention. It should be pointed out that a person skilled in the art can made several improvements and modifications that should be deemed to fall within the protection scope of the present invention, without departing from the principle of the present invention.

What is claimed is:

1. A method for calibrating distributed hydrologic model parameters based on multipoint parallel correction, comprising the following steps:
S1. collecting the locations of precipitation stations and hydrometric stations within a research-targeted basin and their corresponding observed data to give a DEM map and a land use map of the research-targeted basin; performing analysis on the DEM map of the research-targeted basin to give a basin surface file of the research-targeted basin; dividing the research-targeted basin into several sub-basins and giving the precipitation stations within each sub-basin and the weight of each precipitation station, respectively; performing analysis on the land use map to give the impermeability rate of each sub-basin within the research-targeted basin;
S2. adding hydrologic units to the basin surface file to generate a basin model, and configuring corresponding calculation methods for each hydrologic unit;
S3. determining the rainfall process of each sub-basin and the flow process of each hydrometric station section within each sub-basin in the runoff process of flood rainfalls;
S4. dividing the research-targeted basin into several parameter-calibrated units, and creating calculation rules for the parameter-calibrated units;
S5. selecting the corresponding objective functions for each parameter-calibrated unit, and adopting an optimization algorithm to find the minimum value of the objective functions of each parameter-calibrated unit in parallel, gathering the minimum value of the objective functions given by each parameter-calibrated unit, thus being capable to give the optimal parameter of the hydrologic model of the research-targeted basin.

2. The method for calibrating distributed hydrologic model parameters based on multipoint parallel correction according to claim 1, wherein S1 specifically includes the following sub steps:
S11. collecting the positional information of precipitation stations and hydrometric stations with observed data within the research-targeted basin and the observed data corresponding to the precipitation stations and the hydrometric stations, then converting the unequal time interval observed data into hourly observed data by means of an interpolation method; and giving the DEM map and the land use map of the research-targeted basin;
S12. performing hydrologic analysis on the DEM map of the research-targeted basin by means of GIS software to give the basin surface file within the research-targeted basin;
S13. dividing the research-targeted basin into several sub-basins by means of a basin division method; the basin division method ensuring that all the hydrometric stations and the reservoirs of the main stream and larger tributaries having measured data within the research-targeted basin are distributed at the outlet position of each sub-basin;
S14. drawing Thiessen polygons based on the precipitation stations within the research-targeted basin so as to give the influenced precipitation stations of each sub-basin within the research-targeted basin and their respective weights;
S15. analyzing the land use map within the research-targeted basin by means of GIS software to give the impermeability rate of each sub-basin within the research-targeted basin.

3. The method for calibrating distributed hydrologic model parameters based on multipoint parallel correction according to claim 2, wherein when dividing the research-targeted basin into sub-basins, the hydrometric stations and/or reservoirs act as the outlet section of the sub-basin.

4. The method for calibrating distributed hydrologic model parameters based on multipoint parallel correction according to claim 3, wherein S2 specifically includes adding the hydrologic units to the basin surface file to generate the basin model, and configuring the corresponding calculation methods for each hydrologic unit, the hydrologic units including a reservoir unit, a river unit, a sub-basin unit and a confluence unit.

5. The method for calibrating distributed hydrologic model parameters based on multipoint parallel correction according to claim 4, wherein S3 specifically includes the following sub steps:
S31. determining the starting and ending time of rainfall runoff simulation according to the runoff process of the research-targeted basin outlet section and the rainfall process of each precipitation station;
S32. using surface precipitation within each sub-basin to represent the runoff process within each sub-basin, determining the surface precipitation on the basis of multiplication for the precipitation data of each precipitation station within the sub-basin and the Thiessen polygon weights of each precipitation station;
S33. the flow process of each hydrometric station adopting an hourly flow process.

6. The method for calibrating distributed hydrologic model parameters based on multipoint parallel correction according to claim 5, wherein S4 specifically includes the following sub steps:
S41. according to the location of the hydrometric stations with observed data, dividing the research-targeted basin into several parameter-calibrated units, each of which contains at least one sub-basin, and ensuring that the outlet section of each parameter-calibrated unit is a hydrometric station with observed data;
S42. replacing the outflow process of the sub-basin whose outlet section is a reservoir unit with the actual outflow of the reservoir;
S43. for the parameter-calibrated unit that has other parameter-calibrated units flowing in, the outlet section flow of the other parameter-calibrated unit making use of the observed flow as its corresponding outflow data, that is, the inflow data of the parameter-calibrated unit flowed into.

7. The method for calibrating distributed hydrologic model parameters based on multipoint parallel correction according to claim 6, wherein S5 specifically includes the following sub steps:
S51. each parameter-calibrated unit selecting an appropriate hydrologic model parameter to calibrate the objective function according to its respective requirement for basin hydrologic forecast, the objective function being a peak error percentage function or a mean-weighted root-mean-square error function, when required to impose limitations on planning and designing to peak flow, selecting the peak error percentage function as the objective function; when required to reflect the overall situation of the flood process and emphasize the simulation of flood peak flow, selecting the mean-weighted root-mean-square error function as the objective function; the peak error percentage function and the mean-weighted root-mean-square error function being respectively shown in Formula:
$${f}_{1} = 100 \times \vert \frac{{q}_{s} ( peak ) - {q}_{o} ( peak )}{{q}_{o} ( peak )} \vert$$
$${f}_{2} = {\{ \frac{1}{N Q} \times [ {\sum }_{i = 1}^{N Q} {( {q}_{o} ( i ) - {q}_{s} ( i ) )}^{2} ( \frac{{q}_{o} ( i ) + {q}_{o} ( mean )}{2 \times {q}_{o} ( mean )} ) ] \}}^{1 / 2}$$
where f₁ is the peak error percentage function; qₛ(peak) is the peak value to be calculated; qₒ(peak) is the measured peak value; f₂ is the mean-weighted root-mean-square error function; NQ is the number of the hydrograph ordinates to be calculated; qₒ(i) is the measured i^{th} period end flow; qₛ(i) is the i^{th} period end flow to be calculated; i is the time sequence;
S52. for each parameter-calibrated unit, finding the minimum value of its own objective function in parallel by means of one computers with the optimization algorithm, respectively, so as to achieve calibrating the hydrological model parameters within the research-targeted basin; the minimum value of each objective function being the optimal parameter calibrated by each parameter-calibrated unit; gathering the optimal parameters calibrated by each parameter-calibrated unit to give the optimal parameter of the hydrologic model of the research-targeted basin.
